(19) United States
(12) Patent Application Publication
(10) Pub. No.: US 2025/0347996 A1
(43) Pub. Date: Nov. 13, 2025

(54) APPARATUS AND METHOD OF PATTERNING A SUBSTRATE USING AN ORGANOINDIUM RESIST

(71) Applicant: Applied Materials, Inc., Santa Clara, CA (US)

(72) Inventors: Jonathan Hanson MA, Sunnyvale, CA (US); Keith Tatseun WONG, Sunnyvale, CA (US); Huixiong DAI, San Jose, CA (US); Srinivas D. NEMANI, Sunnyvale, CA (US)

(21) Appl. No.: 19/193,203

(22) Filed: Apr. 29, 2025

Related U.S. Application Data
(60) Provisional application No. 63/644,873, filed on May 9, 2024.

(51) Int. Cl. G03F 7/004; G03F 7/36; G03F 7/38

(52) U.S. Cl. CPC G03F 7/0042; G03F 7/36; G03F 7/38

(57) ABSTRACT

Embodiments of the disclosure include a method for preparing a photoresist structure. The method comprising: depositing an underlayer onto a substrate; depositing an EUV photoresist layer onto the underlayer, the EUV photoresist layer comprising at least one indium-based compound; pretreating the EUV photoresist layer to form a pretreated EUV photoresist layer; exposing the pretreated EUV photoresist layer to a treatment gas to form a treated EUV photoresist layer, wherein the exposure of the pretreated EUV photoresist layer to the treatment gas is performed after a plurality of regions of the pretreated EUV photoresist are exposed to electromagnetic radiation; and exposing the treated EUV photoresist layer to a developer gas to form a patterned photoresist layer.

### CROSS-REFERENCE TO RELATED APPLICATIONS

This application claims benefit of U.S. Provisional Patent Application No. 63/644,873, filed May 9, 2024, which is incorporated herein by reference in its entirety.

### BACKGROUND

### Field

Embodiments disclosed herein generally relate to apparatus and patterning processes using radiation sensitive photoresist materials.

### Description of the Related Art

Various lithographic method have been developed and utilized to create integrated circuits (IC). In particular, methods of photolithography have been widely utilized in the development of patterned microelectronic devices. Current industrial and consumer demands require that smaller ICs be developed, thus requiring more sophisticated methods to be developed and utilized. Techniques such as extreme ultraviolet (EUV) lithography have been investigated for developing such integrated circuits from various photoresist materials.

Generally, photoresist materials are radiation sensitive and able to undergo a chemical transformation upon exposure to electromagnetic radiation through a photomask at exposed locations to form a pattern on/within the photoresist material. Such chemical transformations change the properties (e.g., solubility and reactivity) of the radiation-exposed regions as compared to the unexposed regions of the photoresist materials. Thereafter, the photoresist can be developed and the pattern transferred to an underlying thin film or substrate by etching. After the pattern is transferred, the residual photoresist material may be removed.

Several properties are important in lithographic processes, such as sensitivity, resolution, lower line-edge roughness (LER), etch resistance, and the ability to form thinner layer. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures, and enable the formation of thinner films. Thinner films increase the efficiency of the lithographic process.

Currently, there is no known material used in EUV lithography that simultaneously meets the material property criteria set forth in the formation of EUV photoresists. Thus, there is a need to develop new photoresist materials, structures, and/or precursors and methods thereof to progress advancements in EUV lithography.

### SUMMARY

Embodiments of the disclosure include a method for preparing a photoresist structure. The method comprising: depositing an underlayer onto a substrate; depositing an EUV photoresist layer onto the underlayer, the EUV photoresist layer comprising at least one indium-based compound; pretreating the EUV photoresist layer to form a pretreated EUV photoresist layer; exposing the pretreated EUV photoresist layer to a treatment gas to form a treated EUV photoresist layer, wherein the exposure of the pretreated EUV photoresist layer to the treatment gas is performed after a plurality of regions of the pretreated EUV photoresist are exposed to electromagnetic radiation; and exposing the treated EUV photoresist layer to a developer gas to form a patterned photoresist layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic block diagram of a method for depositing a metal photoresists onto a substrate and subsequent processing thereof, according to an embodiment.

FIG. 2A is a partial cross-section view of a photoresist structure, according to an embodiment.

FIG. 2B is a partial cross-section view of a photoresist structure, according to an embodiment.

FIG. 2C is a partial cross-section view of a photoresist structure, according to an embodiment.

FIG. 2D is a partial cross-section view of a photoresist structure, according to an embodiment.

FIG. 2E is a partial cross-section view of a photoresist structure, according to an embodiment.

FIG. 3A is a schematic top view of a first type of cluster tool for forming a photoresist structure, according to an embodiment.

FIG. 3B is a schematic top view of a second type of cluster tool for forming a photoresist structure, according to an embodiment.

FIG. 4 is a cross-sectional view of a processing chamber, according to an embodiment.

FIG. 5 is a cross-sectional view of a processing chamber, according to an embodiment.

FIG. 6 is a cross-sectional view of a processing chamber, according to an embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to extreme ultraviolet (EUV) radiation sensitive photoresist materials and processing sequence that can be used to form patterned features in a substrate using a EUV radiation sensitive photoresist material. In some embodiments, the EUV radiation sensitive photoresist material includes an indium based radiation sensitive photoresist material that is utilized with one or more of the methods of manufacturing and patterning described herein. One embodiment pertains to methods of manufacturing ultrathin, high performance EUV sensitive photoresist layers, for example, formed by an atomic layer deposition (ALD), plasma enhanced ALD (PEALD), chemical vapor deposition (CVD), plasma enhanced CVD (PECVD), or other useful deposition process. However, aspects of the disclosure provided herein are not limited to EUV materials or processing methods. In other specific embodiments, the radiation used in the patterning process can be far ultraviolet, X-ray and electron beam that can be used during the patterning process. According to other embodiments, photoresist materials may also be formed that are sensitive to other forms of irradiation such as, X-ray, electron beam, and other radiation sources. Collectively, such radiation including EUV, far UV, electron beam (EB), and X-ray will be considered suitable forms of radiation methods.

As used herein, “far UV” refers to radiation at a wavelength below 200 nm. “Extreme UV” (EUV) refers to radiation in the approximate range of 4 nanometers (nm) to 121 nm, and in specific embodiments, in the range of 10 nm to 15 nm. “Electron beam” lithography, “E-beam” lithography (EBL) refers to lithography using an electron beam generated from a source, for example LaB₆, which is made to pass through an assembly of lenses and manipulated by deflectors, etc. to expose resist film. “X-ray” lithography refers to techniques for exposing photoresist using x-ray radiation. As used herein, the terminology “metal” and “metal oxide” refers to metal elements in the periodic table, metalloids such as silicon and germanium, and oxides of metals and metalloids. Specific materials according to one or more embodiments include but are not limited to indium, silicon, germanium, tin, hafnium, zirconium, titanium, group V and VI metals and oxides thereof.

As used herein, the term “processing” includes deposition of a material or photoresist, patterning, exposure, development, etching, cleaning, and/or removal of the material or photoresist as required in forming a described structure.

As used herein, a “deposition gas”, “process gas”, or a “source gas” refers to a single gas, multiple gases, a gas containing a plasma, and/or combinations of gas(es) and/or plasma(s). A deposition gas may contain at least one reactive compound for a vapor deposition process. The reactive compounds may be in a state of gas, plasma, vapor, during the vapor deposition process. Also, a process may contain a purge gas or a carrier gas and not contain a reactive compound.

A “pulse” or “dose” as used herein is intended to refer to a quantity of a source gas that is intermittently or noncontinuously introduced into the process chamber. The quantity of a particular compound within each pulse may vary over time, depending on the duration of the pulse. The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

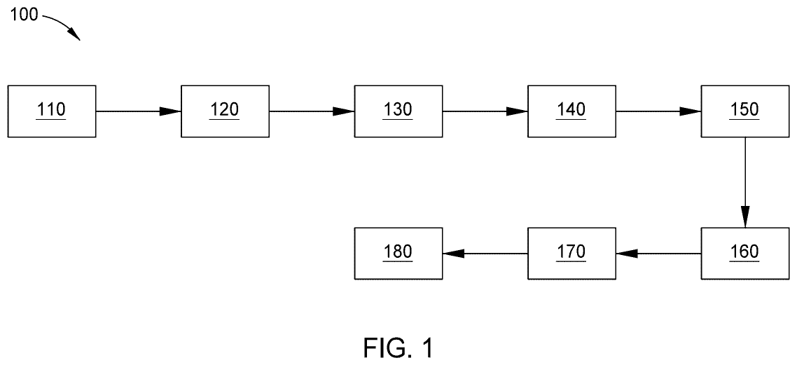

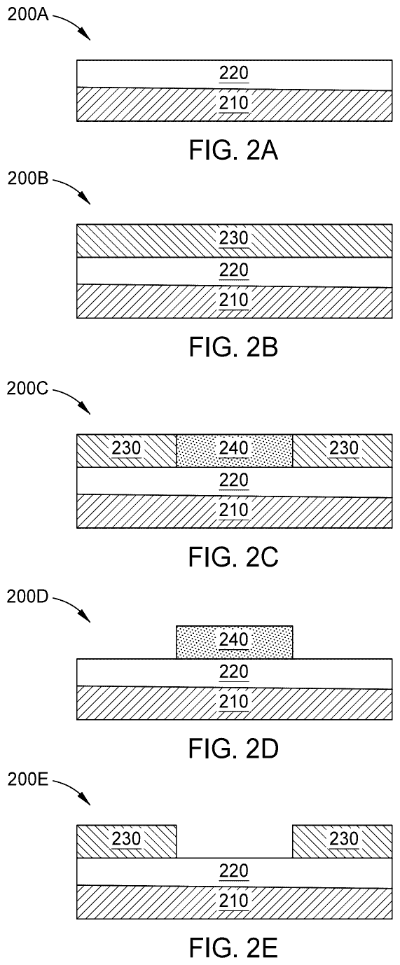

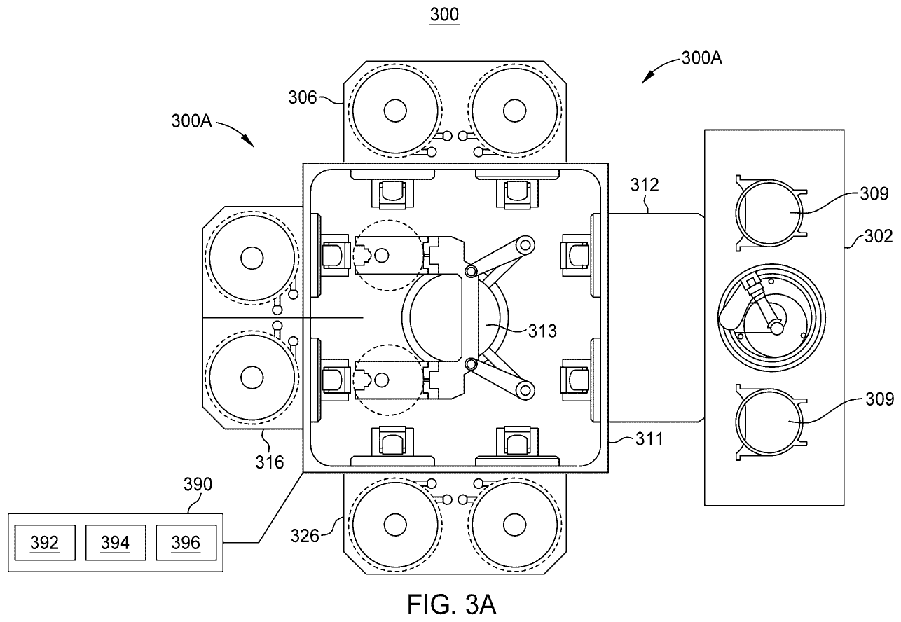

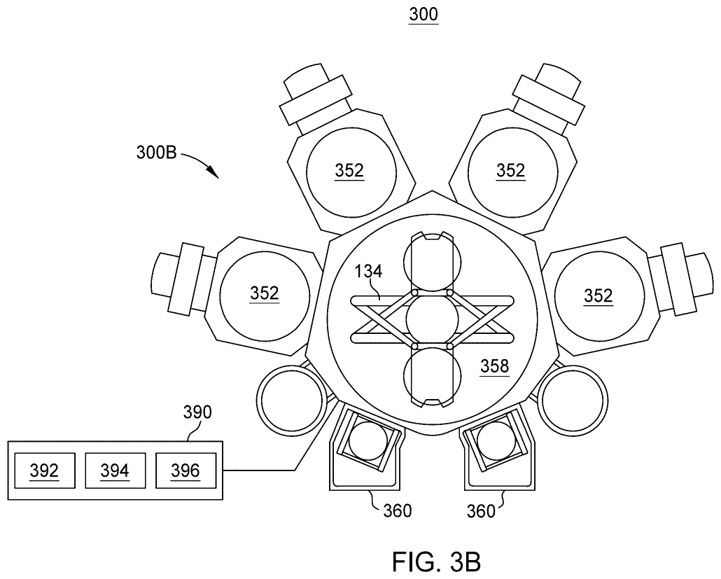

FIG. 1 is a schematic block diagram of a method 100 for depositing a metal photoresist onto a substrate and subsequent processing thereof, according to one or more embodiments. FIGS. 2A-2D are partial schematic side cross-sectional views of a photoresist structure 200a-d during the method 100, according to one or more embodiments. One or more of the operations performed during the execution of method 100 may be performed in any one or more suitable processing chambers that are part of a processing system 300, as shown in FIGS. 3A and 3B. FIGS. 3A and 3B illustrate examples of a first type of processing system 300A and a second type of processing system 300B, respectively.

Generally, organoindium photoresists of the present disclosure can be formed via a series of deposition and treatment processes. FIG. 3A shows a first example of a processing system 300 for forming a photoresist structure, in which embodiments of the present disclosure may be incorporated. The first type of processing system 300, which is referred to herein as processing system 300A, illustrates one embodiment of a Producer™ processing system, commercially available from Applied Materials, Inc., of Santa Clara, Calif. The processing system 300A is a self-contained system having the necessary processing utilities supported on a mainframe structure 301. The processing system 300A generally includes a front end staging area 302 where substrate cassettes 309 are supported and substrates are loaded into and unloaded from a loadlock chamber 312, a transfer chamber 311 housing a substrate handler 313, a series of tandem process chambers 306, 316, and 326 mounted on the transfer chamber 311, and a back end 338 which houses the support utilities needed for operation of the processing system 300A, such as a gas panel 303, and a power distribution panel 305. A system controller 390 contains computer and other circuitry for automation of tasks.

Each of the tandem process chambers 306, 316, and 326 includes two processing regions for processing the substrates. While not intending to limit the scope of the disclosure provided herein, in some embodiments, the two processing regions share a common supply of gases, common pressure control and common process gas exhaust/pumping system. The arrangement and combination of chambers may be altered for purposes of performing specific process steps. Any of the tandem process chambers 306, 316, and 326 can contain processing hardware according to aspects of the disclosure as described below that includes an apparatus for vapor depositing an underlayer onto a substrate, an apparatus for vapor depositing a photoresist over an underlayer, and an apparatus having the necessary components for treating the photoresist layer and preparing/developing a photoresist structure. In one embodiment, tandem process chambers 306 and 316 are configured for pre-processing, depositing of EUV photoresist layers, and treatment of the EUV photoresist layers, while chamber 326 are configured to perform a EUV lithographic process, which may include delivering heat and/or EUV wavelength energy to the substrate.

In general, a system controller 390 may be used to control one or more components found in either of the types of the processing systems 300A or 300B. The system controller 390 is generally designed to facilitate the control and automation of the processing system 300 and typically includes a central processing unit (CPU) 392, memory 394, and support circuits 396. The CPU 392 may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power source variables, gas flows, chamber pressure, chamber process time, I/O signals, etc.) The memory 394 is connected to the CPU 392, and may be one or more of a readily available type of a memory, such as random access memory (RAM), read only memory (ROM), floppy disk, hard disk, or any other form of digital storage, local or remote. Software instructions and data can be coded and stored within the memory 394 for instructing the CPU 392. The support circuits 196 are also connected to the CPU 392 for supporting the processor in a conventional manner. The support circuits 396 may include cache, power supplies, clock circuits, input/output circuitry, subsystems, and the like. A program (or computer instructions) readable by the system controller 390 determines which tasks are performable on a substrate. Preferably, the program is software readable by the system controller 390 that includes code to perform tasks relating to monitoring, execution and control of the movement, support, and/or positioning of a substrate along with the various process recipe tasks and various chamber process recipe steps being performed in the processing system 300. In one embodiment, the system controller 390 also contains a plurality of programmable logic controllers (PLC's) that are used to locally control one or more modules in the processing system 300A, 300B, and a material handling system controller (e.g., PLC or standard computer) that deals with the higher level strategic movement, scheduling and running of the processing system 300.

In one embodiment, a substrate can be provided to a cluster tool, such as the cluster tools shown in FIGS. 3A-3B, which is configured with processing chambers that are adapted to perform an atomic layer deposition (ALD), plasma enhanced ALD (PEALD), chemical vapor deposition (CVD), or plasma enhanced CVD (PECVD) of a EUV photoresist material, an etching process, a photoresist bake process, a dry develop process, and/or one or more treatment processes, such as exposing a substrate to radicals, and/or UV/thermal treatment. In this example, the cluster tool is configured for simultaneously transporting and processing two substrates.

Similarly, single-wafer cluster tools, such as the Endura® or Centura® systems manufactured by Applied Materials, can be utilized for transporting and processing a single substrate within any of a number of processing chambers installed on the systems. In one example, as shown in FIG. 3B, the second type of processing system 300B will include multiple single substrate processing chambers 352 mounted on a centralized vacuum chamber, called a transfer chamber 358, for transferring substrates from a substrate cassette located in one or more load lock chambers 360, to one or more process chambers 352. This particular tool is shown to accommodate up to four (4) single substrate processing chambers 352 positioned radially about the transfer chamber 358. A cluster tool similar to that shown in FIG. 3B is available from Applied Materials, Inc. of Santa Clara, Calif. The transfer of the substrates between the process chambers 352 is typically managed by a substrate handling robot 366 located in a central transfer chamber 358. After the substrates are processed, they are moved back through the load, lock chamber 360 and into substrate cassettes where the substrates can be moved to the next system for additional processing. Various processes, such as ALD, PEALD, CVD, or PECVD of the EUV photoresist material can be performed in the process chambers 352.

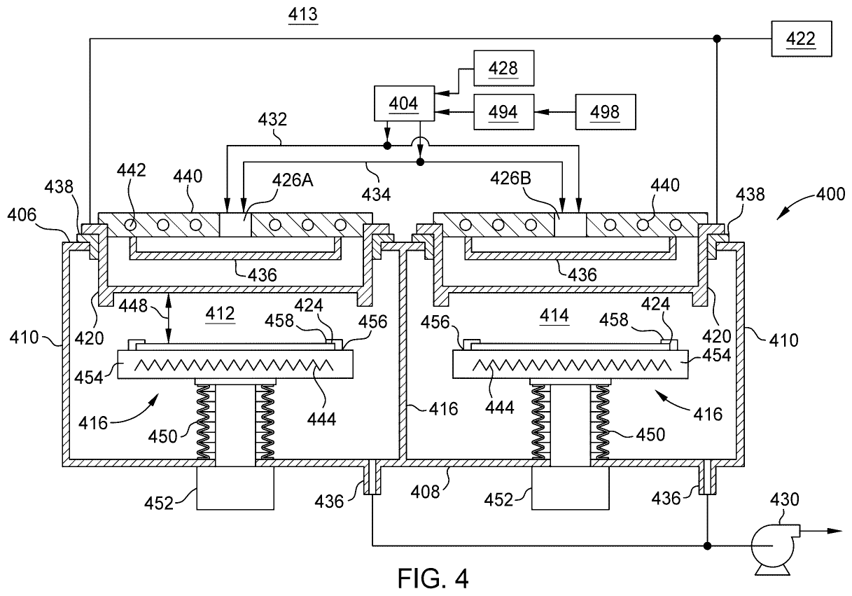

FIG. 4 depicts a processing chamber 400 that includes a gas distribution system 404 coupled to a processing chamber 400. In the embodiment depicted in FIG. 4, the chamber body 400 includes a processing region 412 and a processing region 414.

A showerhead 420 is respectively disposed above each processing region 412, 414 of the processing chamber 400 to provide a uniform distribution of a gas within each of the chambers. In one example, the showerhead 420 enables in-situ deposition of one or more EUV photoresist layers. The showerhead 420 configuration within a processing chamber 400 can also be useful in other portions of a patterning process sequence where uniform gas distribution is desired, such as, exposure of the substrate to a treatment gas, during an etching process and/or the performance of a dry develop process after the photoresist has been exposed to radiation provided from a radiation source.

The processing chamber 400 generally comprises a lid 406, a bottom 408 and sidewalls 410. At least one interior wall 416 is disposed between the lid 406 and bottom 408 of the processing chamber 400 to separate the processing region 412 from the processing region 414. Exhaust ports 446 disposed in the processing chamber 400 generally couple the processing regions 412, 414 to a vacuum pump 430. A throttle valve (not shown) is generally disposed between the pump 430 and each exhaust port 446 and is utilized to regulate pressure in the processing regions 412, 414.

Each processing region 412 and 414 includes a substrate support 454. The substrate support 454 supports a substrate 424 during processing. The substrate support 454 may retain the substrate 424 by a variety of methods, including electrostatic attraction, vacuum or mechanical clamping. Each substrate support 454 is coupled to a lift mechanism 452 that controls the elevation of the substrate support 454 relative to the showerhead 420. The substrate support 454 may be lowered by the lift mechanism 452 to facilitate substrate transfer through substrate access ports (not shown) disposed in the sidewalls 410. Conversely, the substrate support 454 may be raised towards the showerhead 420 to set a gap (or spacing) 448 between the substrate 424 and the showerhead 420. Bellows 450 are coupled between the lift mechanism 452 and the bottom 408 to prevent vacuum leakage.

The substrate support 454 includes a heating element 444 utilized to thermally control the temperature of a substrate 424. The heating element 444 may be a resistive heater, a fluid conduit for flowing a heat transfer fluid or a thermoelectric device among other temperature control devices. In the embodiment depicted, the heating element 444 is a resistive heater capable of heating and maintaining the substrate 424 at a temperature of about 200° C. to about 450° C.

Gas boxes 440 are disposed in the lid 406 of the processing chamber 400 over the substrate support 454 disposed in processing region 412, 414. The gas box 440 may include one or more passages 442 at least partially formed therein to facilitate thermal control of the gas box 440. Each gas box 440 is coupled to the gas distribution system 404. The gas distribution system 404 includes at least a first gas supply circuit 432 and a second gas supply circuit 434. The first gas supply circuit 432 provides at least a first process gas to each processing region 412, 414. The first gas supply circuit 432 is respectively coupled to a first and a second mixing blocks 426A, 426B disposed in the lid 406 of the processing chamber 400. The second gas supply circuit 434 is generally coupled to the first and second mixing blocks 426A, 426B and provides a second process gas thereto. A gas source 428 is coupled directly to the gas distribution system 404. Gas source 428 can be a bottle or bottles of high purity gasses such as, argon (Ar), oxygen (O₂), nitrogen (N₂), helium (He), or hydrogen (H₂). A gas source 428 may also include a precursor source or bubbler, wherein the precursor is a liquid at room temperature and requires a heated line and a “push” gas (e.g., Ar, N₂) for reliable flow to the substrates 424. Gas source 428 can also be a network of connections to a common factory building facility which is configured to provide delivery of high purity gases from a common gas source to individual processing systems. A second gas source 498 is similar to gas source 428 but is coupled to a remote plasma source (RPS) 494. RPS 494 is configured to dissociate molecular species of gases flowing through the RPS by delivering energy to these flowing gases by use of an energy source (not shown) (e.g., microwave, RF or high voltage source). One example of an RPS is Applied Materials' Remote Plasma Source hardware which can be coupled to chambers in order to deliver radicals to substrate surfaces. RPS 494 is coupled to gas distribution system 404 to provide delivery of radicals to substrates 424.

The showerhead 420 is generally coupled to the lid 406 of the processing chamber 400 between each blocker plate 436 and substrate support 454. The blocker plate 436 is coupled to the lid 406 of the processing chamber 400 and forms the first plenum therewith below each mixing block 426A, 426B. The blocker plate 436 is generally perforated to distribute the gases flowing out each mixing block 426A, 426B radially. The showerhead 420 generally distributes process and other gases uniformly to the processing regions 412, 414 to enhance deposition uniformity. In some embodiments, a radio frequency (RF) power source 422 is coupled to the showerhead 420. RF power, applied to the showerhead 420 during processing, typically ignites and sustains a plasma of the mixed process gas(es) and/or other gases within the respective processing regions 412, 414 which generally facilitates lower processing temperatures with increased deposition rates. A dielectric isolator 438 disposed between the showerhead 420 and the lid 406 of the processing chamber 400 is used to electrically isolate the showerhead 420 from the processing chamber 400. In one embodiment, endpoint detection hardware, such as a spectrometer optically coupled to the processing chamber 400 through an optical fiber, can detect the presence or absence of byproducts in a plasma during a plasma treatment used to remove byproducts therefrom.

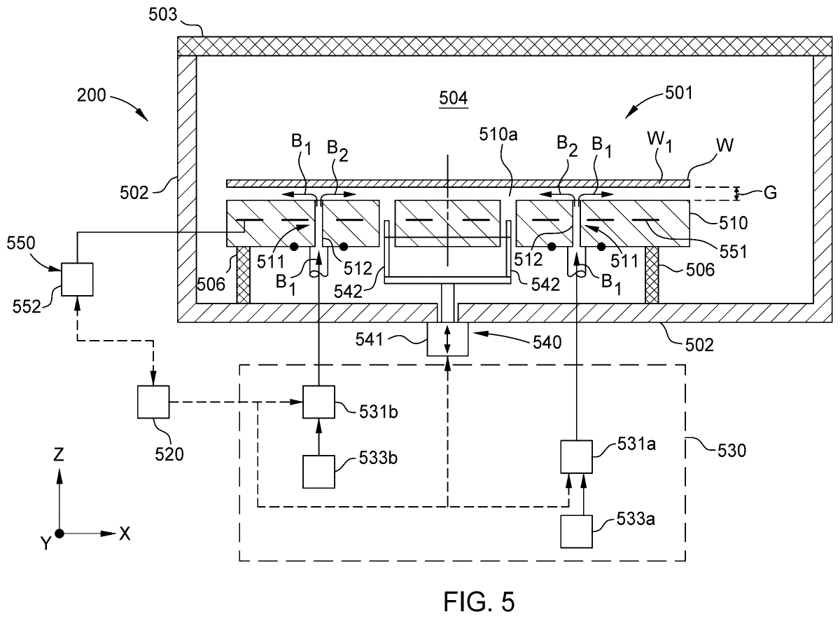

FIG. 5 is a schematic cross-sectional view that illustrates a processing chamber 500 that can be positioned within a processing system 300A, 300B and be used to perform one or more of the operation 110-140 and 160-180 described in method 100, such as operations 130-140 and 160-180. The processing chamber 500 contains one or more walls 502, a lid 503, a substrate lift assembly 540 and a substrate support assembly 501, which is disposed on a support 506 in the processing region 504 of the processing chamber 500. In general, the processing chamber 500 may be an RTP, CVD, PVD, ALD, thermal processing chamber, dry etching, or other similar type of substrate processing chamber. In some embodiments, the lid 503 can include one or more lamps (not shown) that are configured to heat or deliver electromagnetic radiation (e.g., UV wavelengths) through a transparent window and to the exposed surface W₁ of substrate W. The substrate lift assembly 540 generally contains a plurality of lift pins 542 and an actuator 541 (e.g., air cylinder, DC servo motor and lead screw) that are adapted to transfer a substrate to and from the substrate support 510, which is contained in the substrate support assembly 501, and a substrate transferring device.

The substrate support assembly 501 generally contains a substrate support 510, a fluid delivery system 530, temperature control assembly 550, and a system controller 520 (e.g., system controller 390). In one embodiment, a substrate “W” is supported on the substrate support assembly 501 over the fluid delivery system 530 and the ports 511 formed in the substrate support 510. In at least one embodiment, a fluid is provided to a gap “G” formed between the substrate W and the substrate support 510 to improve heat transfer therebetween.

In one embodiment, the temperature control assembly 550 generally contains a heating element 551 that is in thermal contact with the substrate support 510 and a temperature controller 552. The heating element 551 can be a resistive heating element that is embedded within the substrate support 510. In one example, the heating element is adapted to heat a substrate W that is placed in thermal contact with a surface of the substrate support 510 to an elevated temperature, such as between about 50° C. and about 250° C. The temperature controller 552 generally contains a power source (not shown) and a temperature measurement device (not shown) that are adapted to control the temperature of the substrate support 510 using conventional means.

In one embodiment, the fluid delivery system 530 generally contains one or more fluid control components that are used to provide and control the delivery of fluid to the ports 511 formed in the substrate support 510. In one embodiment, the fluid delivery system 530 contains one or more fluid sources (e.g., fluid sources 533a-533b) that deliver fluid to each of the ports 511 using a fluid controlling device (e.g., fluid controlling devices 531a-531b). The fluid controlling devices are adapted to control the flow, velocity and/or pressure of the fluid delivered to the ports 511 by use of commands sent from the system controller 520 (e.g., system controller 390). In one embodiment, the fluid controlling devices (e.g., reference numerals 531a-531b) are conventional mass flow controllers (MFCs) that are in communication with the system controller 520 (e.g., system controller 390). In another embodiment, the fluid controlling devices are a fixed orifice that is configured to deliver desired flows at various known pressures. The control of the substrate movement can also be affected by the type of fluids (e.g., gases, liquids) delivered by the one or more ports, and thus the viscosity, atomic mass, pressure, and density need to be taken into account. The selection of the fluid generally must also take into account its effect on the process performed in the processing region 504.

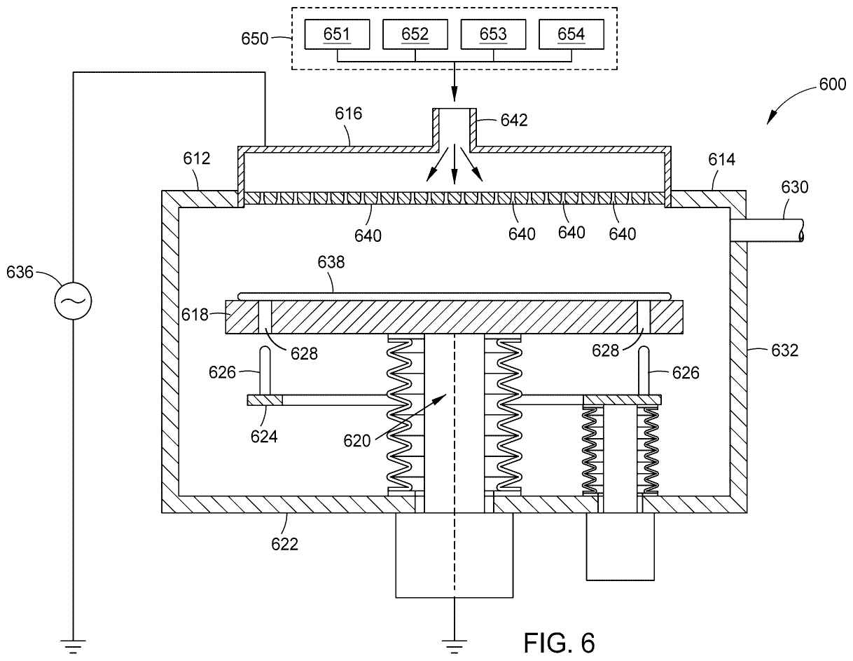

FIG. 6 illustrates a schematic cross-sectional view of a process chamber 600 in which the methods of the present disclosure may also be carried out. In some embodiments, the process chamber 600 can be positioned within a processing chamber position within the processing system 300, such as processing system 300A, 300B. The processing chamber 600 can be used to perform one or more of the operation 110-140 and 160-180 of method 100, such as operations 110-140 and 160-180.

Process chamber 600 includes a deposition chamber 612 that has a top wall 614 with an opening there-through and a first electrode 616, such as a showerhead, within the opening. Within deposition chamber 612 is a susceptor 618 in the form of a plate that extends parallel to the first electrode 616. The susceptor 618 is connected to ground, or alternately biased by use of RF or DC source (not shown), so that it serves as a second electrode. The susceptor 618 is mounted on the end of a shaft 620 that extends vertically through a bottom wall 622 of the deposition chamber 612. The shaft 620 is movable vertically so as to permit movement of the susceptor 618 vertically toward and away from the first electrode 616. A lift plate 624 extends horizontally between the susceptor 618 and the bottom wall 622 of the deposition chamber 612 substantially parallel to the susceptor 618. Lift pins 626 project vertically upwardly from the lift plate 624. The lift pins 626 are positioned to be able to extend through holes 628 in the susceptor 618, and are of a length slightly longer than the thickness of the susceptor 618. While there are only two lift pins 626 shown, there may be more of the lift pins 626 spaced around the lift plate 624. A gas outlet 630 extends through a side wall 632 of the deposition chamber 612 and is connected to a pump for evacuating the deposition chamber 612. A gas inlet pipe 642 extends through the first electrode 616 of the deposition chamber 612, and is connected to a gas source 650 to provide one or more gases through the first electrode 616 and to a substrate 638 disposed on the susceptor 618. The first electrode 616 includes a plate 640 with holes 644 that are configured to deliver the one or more gases to the substrate 638. In some embodiments, the first electrode 616 is connected to an RF power source 636.

As discussed above, the gas source 650 is a precursor delivery system that includes two or more fluid delivery lines that are each configured to deliver a fluid, such as the metal containing precursor, carrier gas, reducing agent containing gas, and/or inert gas at different flow rates, temperatures and/or pressures to the gas inlet pipe 642, first electrode 616, and substrate 638. The gas source 650 can include a first metal containing precursor source 651, a second metal containing precursor source 652, a reducing agent containing gas source 653 and a carrier gas source 654. In some embodiments, the first metal containing precursor source 651 and the second metal containing precursor source 652 include heating elements that each configured to heat and control the temperature of one or more components (e.g., ampoules and/or fluid deliver lines) within the sources during processing. In one example, as discussed above, the first metal containing precursor source 651 and the second metal containing precursor source 652 each include an ampoule that contains the same metal containing precursor that are heated to different fluid delivery temperatures.

### Processing Sequence Example

As discussed above, FIG. 1 illustrates one embodiment of a series of method steps 100 that generally include processing operations that are used to pre-treat, deposit, expose and develop a photoresist material layer formed on a substrate surface. The lithographic process sequence may generally contain the following: an underlayer formation operation 110, a EUV photoresist layer formation operation 120, a post EUV photoresist treatment operation 130, a pre-exposure treatment operation 140, an EUV exposure operation 150, a post exposure and pre-develop treatment operation 160, a develop operation 170, and a post develop treatment operation 180. In other embodiments, the sequence of the method steps 100 may be rearranged, altered, one or more steps may be removed, additional steps added or two or more steps may be combined into a single step without varying from the basic scope of the disclosure provided herein. As will be discussed further below, in some embodiments of method 100, operations 110-140 are performed in a first processing system, such as either processing system 300A or 300B, the processes used to perform operation 150 are performed in lithographic processing system (e.g., stepper), and operations 160-180 are performed in the first processing system or a second processing system.

Referring back to FIGS. 1 and 2, at operation 110 of method 100 an underlayer 220 may be deposited over a substrate 210 of a photoresist structure 200a, as depicted in FIG. 2A. In some embodiments, the substrate 210 includes any substrate material or surface thereof suitable for use in manufacturing ultrathin, high performance extreme ultraviolet (EUV) sensitive photoresist layers. In some embodiments, the underlayer 220 deposited over a hard mask that is formed over one or more dielectric and/or metal containing layers, which are to be patterned in a subsequent device manufacturing process. In some embodiments, the underlayer 220 includes an amorphous carbon underlayer and/or a spin-coated organic underlayer. The underlayer 220 may include a silicon oxycarbide (SiOC) containing underlayer. The substrate 210 may include materials such as crystalline silicon (e.g., Si<I00> or Si<III>), silicon oxide, strained silicon, silicon germanium, doped or undoped polysilicon, doped or undoped silicon wafers, or III-V materials. In some examples, a substrate may have various dimensions, such as 200 mm, 300 mm, or 450 mm wafers, as well as, rectangular or square panes.

In at least one embodiment, the substrate 210 has a surface which may be of any substrate or material surface formed on a substrate upon which film processing is performed during a fabrication process. For example, the substrate surface on which processing can be performed includes materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride, aluminum, copper, or any other conductor or conductive or non-conductive barrier layer useful for device fabrication.

In some embodiments, the underlayer 220 is an amorphous carbon underlayer, a spin-coated organic underlayer, or a combination thereof. The underlayer 220 may be deposited onto the substrate 210 by a variety of methods, such as CVD, PECVD, high density plasma CVD (HDPCVD), or combinations thereof. The underlayer 220 may include carbon and hydrogen, or carbon, hydrogen, and oxygen, or carbon, hydrogen, nitrogen, and oxygen, as well as other dopant atoms depending on the specific precursors employed in the deposition. In at least one embodiment, the underlayer 220 is subjected to additional treatments and/or treatment processes to incorporate one or more metal and/or metalloid atoms onto and/or into the surface of the underlayer 220.

In one embodiment, the underlayer 220 is an amorphous carbon underlayer formed from a gas mixture of a hydrocarbon compound and an inert gas such as argon, helium, xenon, krypton, neon, or combinations thereof. In specific embodiments, the carbon source is a gaseous hydrocarbon, and typically an unsaturated hydrocarbon, a material containing a double or triple bond between carbon atoms such that it is prone to polymerization. In one embodiment, the hydrocarbon compound has a general formula of CₓH₂ₓ or CₓH₂ₓ₊₂, where x has a range of between 2 and 6. For example, propylene (C₃H₆), propane (C₃H₈), butane (C₄H₁₀), butylene (C₄H₈), butadiene (C₄H₆), pentane (C₅H₁₂), hexane (C₆H₁₄), or cyclohexane (C₆H₁₂) as well as combinations thereof, may be used as the hydrocarbon compound. In some embodiments, the hydrocarbon compound can include propyne (C₃H₄), acetylene (C₂H₂), 5-vinyl-2-norbornene, and combinations thereof. In some embodiments, the hydrocarbon compound can include allyl alcohol (C₃H₆O) and its variants. Similarly, a variety of gases such as hydrogen, nitrogen (N₂), ammonia (NH₃), oxygen (O₂), or combinations thereof, among others, may be added to the gas mixture, if desired. One or more other types of dopants, such as silicon (Si), boron (B), phosphorous (P), arsenic (As), germanium (Ge), indium (In), or other useful element may be added to the underlayer 220 to improve its optical, mechanical, or chemical properties. One or more dopant containing gases may thus be used in the formation of the underlayer 220, such as silane (SiH₄), germanium hydride (GeH₄), diborane (B₂H₆), phosphane (PH₃), arsine (AsH₃), Iodoethane (C₂H₅I), and Iodomethane (CH₃I). In at least one embodiment, the one or more dopant containing gases include tris(dimethylamino)silane, tetrakis(dimethylamino)silane, tetravinylsilane, trisilylamine, and combinations thereof. In some embodiments, the dopant gases can include a metal containing precursor such as tin (Sn) or indium (In). In one example, the metal containing precursor includes tetramethyl tin (C₄H₁₂Sn) or trimethylindium (In(CH₃)₃). Gases such as Ar, He, and N₂ may be used to control the density and deposition rate of the amorphous carbon layer. The addition of hydrogen or ammonia can be used to control the hydrogen ratio of the amorphous carbon underlayer, as discussed below.

The underlayer 220, such as the amorphous carbon underlayer, may be deposited onto the substrate 210 at temperature of about 100° C. to about 700° C., a chamber pressure of about 10 millitorr (mTorr) to about 20 Torr, a hydrocarbon gas flow rate of about 50 sccm to about 500 sccm an RF power of between about 0.01 W/in² and about 100 W/in² at one or more RF frequencies between 2 MHz and 60 MHz (e.g., 13.56 MHz), such as between about 0.05 W/in² and about 10 W/in², and a showerhead to substrate spacing of between about 300 mils to about 600 mils (FIG. 4 or 6). The underlayer 220 can be deposited to a thickness between about 200 Å and about 10,000 Å. The underlayer 220 may be deposited onto to substrate at a deposition rate of about 100 Å/min to about 5,000 Å/min. The process parameters described above can be implemented on 200 mm or 300 mm substrates in a process chamber, such as any one or more process chambers described above.

The underlayer 220 may have an adjustable carbon: hydrogen ratio that ranges from about 10% hydrogen to about 90% hydrogen, such as between 40% and 70% hydrogen. Controlling the hydrogen ratio of the amorphous carbon layer is desirable for tuning its optical properties as well as its etch selectivity. Specifically, as the hydrogen ratio decreases, the optical properties of the as-deposited layer such as for example, the absorption coefficient (k) increases. Similarly, as the hydrogen ratio decreases, the etch resistance of the underlayer 220 may increase, depending on the etch chemistry used.

The formation of an underlayer 220 can be useful to promote adhesion between the subsequently formed EUV photoresist layer 230 and the underlying layers formed on the substrate 210, such as an underlying hard mask layer. Moreover, controlling the composition of the underlayer 220, such as controlling the carbon to hydrogen ratio of the amorphous carbon layer can also be used to control the absorption of EUV photons provided during an exposure step, which in turn can lead to the generation of excess secondary electrons, which can be used to catalyze additional reactions within the resist and improve the performance of the EUV photoresist patterning process. In at least one embodiment, the composition of the underlayer 220 may be controlled and/or altered through the introduction of a dopant, such as silicon (Si), boron (B), phosphorous (P), arsenic (As), germanium (Ge), indium (In), and combinations thereof, to the underlayer 220. Without being bound by theory, introducing a dopant to the underlayer 220 can improve its optical, mechanical, and/or chemical properties.

At operation 120 of the method 100, a EUV photoresist layer 230 is deposited onto the underlayer 220 of the photoresist structure 200b, as depicted in FIG. 2B. In some embodiments, the EUV photoresist layer 230 is deposited on the underlayer 220 by any suitable method or technique, such as “wet” and “dry” deposition techniques. The EUV photoresist layer 230 may be deposited by a dry deposition process, such as a vapor phase deposition process. The EUV photoresist layer 230 deposition process and the underlayer deposition process performed in operation 110 can both be performed in a substrate processing system (e.g., processing 300A or 300B) so that the substrate is maintained in a vacuum environment during both processing operations and a robot transfer process sequence used to transfer the substrate between an underlayer deposition chamber and the EUV photoresist deposition chamber. In a vapor phase deposition process, a metal precursor and at least one of oxidant and/or a nitridant may be provided to a vacuum chamber, with the metal precursor and the oxidant reacting to deposit the EUV photoresist layer 230 over a surface of the underlayer 220. Such dry deposition processes may be characterized as a chemical vapor deposition (CVD) process, an ALD process, a plasma enhanced CVD (PECVD) process, or a PEALD process. The EUV photoresist layer 230 may be deposited over the surface of the underlayer 220 using an ALD, CVD, PECVD or PEALD process within any one or more processing chambers of the processing system 300A, 300B described above. Dry deposition techniques, such as ALD, provide the unique ability to assemble a film with not only atomic layer control of thickness but also the placement of reactive functionality that can survive the deposition conditions and create solubility during a subsequent develop process (e.g., reactivity with a dry develop gas or an aqueous developers) together with the formation of a high sensitivity to EUV radiation (and other radiation such as far UV, DUV, and electron beam). The EUV photoresist layer 230 can be used to form a negative tone resist, which involves cross-linking within the EUV exposed regions of the EUV photoresist layer 230 which causes a loss of solubility of the exposed photoresist material, or a positive tone resist which causes the breaking of bonds within the EUV photoresist which causes an increased solubility of the exposed resist during a subsequent develop process.

There are numerous potentially useful combinations of reactive substituents which can be utilized to impart sensitivity to radiation such as e-beam, x-ray, EUV and far UV light. While materials with such functionality can be prepared in forms suitable for spin-coating, formulations for doing so can prove either too unstable (for example, to traces of air, moisture, handling at room temperature, etc.) or require too high an EUV dose during subsequent exposure step to be practical. Because embodiments of the EUV photoresist formation operation are performed in a vacuum chamber environment, reliable coating, handling and stable EUV photoresist films can be achieved even with materials such as indium based compounds. Embodiments of the present disclosure permit the use of less stable radiation sensitive materials and other substituents sensitive to e-beam, x-ray, far UV, and EUV radiation, to form a defect-free film to be reliably and repeatedly be formed.

In some embodiments, photoresists are manufactured using an ALD process to form a layer that can be patterned by exposure to some form of radiation, such as e-beam, x-ray, far UV, or EUV light. In one example, an ALD process is used in which a first chemical precursor (“A”) may be pulsed into a processing region of a suitable deposition chamber to deliver a metal species containing substituents to the surface of a substrate. A first chemical precursor “A” is selected so its metal reacts with suitable underlying species on the surface of the substrate (e.g., —OH or —NH groups) to form a new self-saturating surface. Excess unused reactants and the reaction by-products may be removed from the deposition chamber via an evacuation-pump down step and/or by a flowing inert purge gas through the deposition chamber for a period of time. Then a non-metal reactant “B” may be delivered to the substrate surface, wherein the previously reacted terminating substituents or ligands of the first half reaction are reacted with new ligands from the “B” reactant, creating an exchange by-product. The non-metal reactant “B” may include a vapor, gas, or plasma containing an active hydrogen, oxygen or nitrogen species. For example, the non-metal reactant “B” may include water, a peroxide/water mixture (e.g., water mixed with H₂O₂), a water/acid mixture (e.g., water mixed with HCl), a water/base mixture (e.g., water mixed with NH₃), or a combination thereof. A second purge period may be utilized to remove unused reactants and/or reaction by-products still remaining in the deposition chamber. Thereafter, a second metal-containing precursor “A” with reactive moieties cross-linkable with the substituents present in the first “A” precursor may be introduced to the deposition chamber and pulsed to the substrate surface. The second metal-containing precursor “A” can include the same composition of the first metal-containing precursor “A” or a different composition from the first metal-containing precursor “A”. Without being bound by theory, introducing the second metal-containing precursor “A” to the deposition chamber promotes the reaction of the reactive moieties of second metal-containing precursor “A” with the substituents of the first metal-containing precursor “A” and/or the ligands of the non-metal reactant “B”. A third purge may then be utilized to remove unused reactants and/or reaction by-products present within the deposition chamber. In at least one embodiment, the deposition cycle of pulses of the first metal-containing precursor “A”, the non-metal reactant “B”, and the second metal-containing precursor “A” results in the formation of a deposited layer that is partially unreacted and is soluble in a developer solution. The alternating exposure of the surface to reactants “A” and “B” may be continued until the desired thickness of the EUV sensitive film is achieved. In some embodiments, the EUV 6718374 21 sensitive film has a thickness ranging from about 5 nm to about 40 nm, such as about 10 nm to about 30 nm, such as about 15 nm to about 25 nm, alternatively about 5 nm to about 10 nm, alternatively about 10 nm to about 15 nm, alternatively about 15 nm to about 20 nm, alternatively about 20 nm to about 25 nm, alternatively about 25 nm to about 30 nm, alternatively about 30 nm to about 40 nm. It will be understood that the “A”, “B”, and purge gases can flow simultaneously, and the substrate and/or gas flow nozzle can oscillate such that the substrate is sequentially exposed to the A, purge, and B gases as desired.

In some embodiments, the first chemical precursor “A” includes a compound having one or more of indium, silicon, germanium, tin, hafnium, zirconium, titanium, group V and VI metals and oxides thereof. In at least one embodiment, the first chemical precursor “A” includes an indium based compound, such as an organoindium compound. The indium based compound may include a chemical structure represented by InRₓL_{y}, wherein R is an organic group, L is a ligand, and both x and y are integers independently ranging from 0 to 3. In some embodiments, the R group of the indium based compound is an organic group, such as an alkyl group having any number of carbon atoms (e.g., C₁ to C₂₀). The R group may include one or more of methyl, ethyl, i-propyl, n-propyl, t-butyl, i-butyl, n-butyl, sec-butyl, n-pentyl, i-pentyl, t-pentyl, sec-pentyl, cyclopentadienyl, and combinations thereof. In some embodiments, the L group of the indium based compound includes one or more ligands that are prone to partial or total removal upon deposition. The L group may include one or more of an amino, a methyl amino, a dimethyl amino, an alkoxy, a carboxylate, a halide, an acetate, an acetylacetonate, and combinations thereof. The indium based compound may include one or more of trimethyl indium, indium acetate (hydrate), indium nitrate (hydrate), indium acetylacetonate, and combinations thereof.

In some embodiments, the non-metal reactant “B” can include one or more of water, ammonia, methanol, ethanol, and combinations thereof. The non-metal reactant “B” may be activated by one or more remote plasma sources, and can be dosed concurrently or sequentially with the first chemical precursor “A”.

As shown in FIG. 2B, during operation 120 of the method 100, a EUV photoresist layer 230 is deposited onto the underlayer 220 of the photoresist structure 200b using an vapor phase deposition process, such as an ALD or PE-ALD process. The ALD process may be conducted using one of the previously described process chambers. In another embodiment, a chamber configured to operate in both an ALD mode as well as a conventional CVD mode may be used to deposit photoresist materials. The ALD process provides that the processing chamber may be pressurized at a pressure within a range from about 0.01 Torr to about 100 Torr, for example from about 0.1 Torr to about 10 Torr, and more specifically, from about 0.5 Torr to about 5 Torr. Also, according to one or more embodiments, the chamber or the substrate may be heated to a temperature of less than about 500° C., for example, about 400° C. or less, such as within a range from about 50° C. to about 400° C., and in other embodiments less than about 300° C., less than about 200° C., or less than about 100° C. The one or more EUV photoresist compounds may be introduced into the chamber at a flow rate from about 10 mg/minute to about 5000 mg/minute, such as at a flow rate from about 10 mg/minute to about 3000 mg/minute. The optional oxidizing gas (e.g., O₂) may be introduced into the chamber at a flow rate from about 0 sccm and about 1000 sccm, such as at a flow rate from about 0 sccm to about 500 sccm. A dilution or carrier gas, such as helium, argon, or nitrogen, may also be introduced into the chamber at a flow rate between about 10 sccm and about 10000 sccm, such as at a flow rate from about 50 sccm to about 5000 sccm. The plasma may be generated by applying a power density ranging between about 0.01 W/cm² and about 2.8 W/cm², which is a RF power level of between about 10 W and about 2000 W, such as 0.07 W/cm² and about 1.4 W/cm², which is a RF power level of between about 50 W and about 1000 W for a 300 mm substrate, may be used. The RF power is provided at a frequency between about 0.01 MHz and 300 MHz, such as about 13.56 MHz. The RF power may be provided at a mixed frequency, such as at a high frequency of about 13.56 MHz and a low frequency of about 350 KHz. The RF power may be cycled or pulsed to reduce heating of the substrate. The RF power may also be continuous or discontinuous.

At operation 130 of the method 100, a pre-exposure bake is applied to the deposited EUV photoresist layer 230 of the photoresist structure 200b. Baking the deposited EUV photoresist layer 230 may include heating the deposited EUV photoresist layer 230 within a separate processing chamber, such as processing chamber 500 (FIG. 5). During such pre-exposure baking processes, the temperature within the processing chamber may be in the range of about 80° C. to about 250° C., such as about 100° C. to about 200° C., such as about 125° C. to about 175° C., alternatively about 80° C. to about 100° C., alternatively about 100° C. to about 125° C., alternatively about 125° C. to about 150° C., alternatively about 150° C. to about 175° C., alternatively about 175° C. to about 200° C., alternatively about 200° C. to about 250° C. The deposited EUV photoresist layer 230 may be exposed to the pre-exposure bake for about 5 seconds(s) to about 300 s, such as about 50 s to about 250 s, such as about 100 s to about 200 s, alternatively about 5 s to about 50 s, alternatively about 50 s to about 100 s, alternatively about 100 s to about 150 s, alternatively about 150 s to about 200 s, alternatively about 200 s to about 250 s, alternatively about 250 s to about 300 s. The pressure within the processing chamber during operation 130 may be maintained in the range of about 0.1 Torr to about 760 Torr, such as about 0.1 Torr to about 500 Torr, such as about 0.1 Torr to about 100 Torr. The pre-exposure bake may be conducted with a constant purge gas flow to remove volatile by-products found in the processing region of the processing chamber. The purge gas may include one or more of Ar, N₂, He, and combinations thereof. Furthermore, one or more of H₂, H₂O, NH₃, O₂, and combinations thereof may be flowed into the processing chamber during operation 130. In at least one embodiment, the gas(es) flowed into the processing chamber during operation 130 may be enhanced/activated by a remote or local plasma source. During operation 130, the one or more gas(es) may be flowed into the processing chamber at a rate of about 100 sccm to about 10000 sccm, such as about 1000 sccm to 5000 sccm.

Without being bound by theory, the pre-exposure bake can increase the background indium oxidation or nitridation levels of the EUV photoresist layer 230, ultimately increasing the degree to which cross-links form within the EUV photoresist layer 230. This, in turn, allows for modulation of the exposure dosing level to target different patterning applications and tradeoffs. For example, by conducting the pre-exposure bake, the EUV dose (subsequently applied during operation 150) could be reduced in the expense of chemical contrast. Furthermore, the pre-exposure bake may also provide the EUV photoresist layer 230 with an improved photoresist layer density, improved adhesion to the underlayer 200, and/or fine-tuned composition.

At operation 140 of the method 100, a pre-exposure UV treatment is applied to the deposited EUV photoresist layer 230 of the photoresist structure 200b. The pre-exposure UV applied to the deposited EUV photoresist layer 230 may include exposing the deposited EUV photoresist layer 230, within the same processing chamber as operation 130 or a separate processing chamber, to a blanket UV radiation provided from a UV lightsource that is capable of providing UV light of homogenous intensity to the surface of the EUV photoresist layer 230. The UV lightsource may be capable of providing UV light at a wavelength ranging from about 125 nm to about 405 nm, such as about 157 nm to about 365 nm, such as about 193 nm to about 254 nm, alternatively about 125 nm to about 157 nm, alternatively 157 nm to about 193 nm, alternatively about 193 nm to about 248 nm, alternatively about 248 nm to about 254 nm, alternatively about 254 nm to about 365 nm, alternatively about 365 nm to about 405 nm. During such pre-exposure UV treatment processes, the temperature within the processing chamber may be in the range of about room temperature (e.g., 20° C.) to about 250° C., such as about 80° C. to about 250° C., such as about 100° C. to about 200° C., such as about 125° C. to about 175° C., alternatively about 80° C. to about 100° C., alternatively about 100° C. to about 125° C., alternatively about 125° C. to about 150° C., alternatively about 150° C. to about 175° C., alternatively about 175° C. to about 200° C., alternatively about 200° C. to about 250° C. The temperature of the photoresist structure 200b within the processing chamber may be controlled by use of a heat-exchanging device that includes one or more chiller elements and/or heating elements. The deposited EUV photoresist layer 230 may be exposed to the pre-exposure UV treatment for about 5 seconds(s) to about 300 s, such as about 50 s to about 250 s, such as about 100 s to about 200 s, alternatively about 5 s to about 50 s, alternatively about 50 s to about 100 s, alternatively about 100 s to about 150 s, alternatively about 150 s to about 200 s, alternatively about 200 s to about 250 s, alternatively about 250 s to about 300 s. The pressure within the processing chamber during operation 140 may be maintained in the range of about 0.1 Torr to about 760 Torr, such as about 0.1 Torr to about 500 Torr, such as about 0.1 Torr to about 100 Torr. The pre-exposure UV treatment may be conducted with a constant purge flow to remove by-products from the process chamber. The purge gas may include one or more of Ar, N₂, He, and combinations thereof. Furthermore, one or more of H₂, H₂O, NH₃, O₂, and combinations thereof may be flowed into the processing chamber during operation 140. In at least one embodiment, the gas(es) flowed into the processing chamber during operation 140 may be enhanced/activated by a remote or local plasma source. During operation 140, the one or more gas(es) may be flowed into the processing chamber at a rate of about 100 sccm to about 10000 sccm, such as about 1000 sccm to 5000 sccm.

Without being bound by theory, the pre-exposure UV treatment can increase the background indium oxidation or nitridation levels of the EUV photoresist layer 230, ultimately increasing the degree to which cross-links form within the EUV photoresist layer 230. This, in turn, allows for modulation of the exposure dosing level to target different patterning applications and tradeoffs. For example, by conducting the pre-exposure UV treatment, the EUV dose (subsequently applied during operation 150) can be reduced in the expense of chemical contrast, thereby improving patterning properties, such as line-edge-roughness (LER) and critical dimensions, increase substrate throughput, and reduce the cost of exposure process. Furthermore, the pre-exposure UV treatment may also provide the EUV photoresist layer 230 with improved adhesion to the underlayer 200 and/or fine-tuned composition.

At operation 150 of the method 100, the EUV photoresist layer 230 of the photoresist structure 200b is exposed to irradiation with a selected pattern by an electromagnetic radiation to produce a photoresist structure 200c having an EUV photoresist layer 230 with a radiation formed pattern, as depicted in FIG. 2C. A lithographic apparatus used to perform operation 150 can include an EUV radiation source that is configured to deliver a wavelength within a range of about 4 nm to about 121 nm, such as for example 6.7 nm or 13.5 nm. The radiation formed pattern includes the radiation exposed regions 240 of the EUV photoresist layer 230. As a result of operation 150 of the method 100, the photoresist structure 200c includes both unexposed regions of the EUV photoresist layer 230 and radiation exposed regions 240. The radiation exposed regions 240 of the radiation formed pattern were exposed to one or more types of electromagnetic radiation selected from UV, EUV, deep ultraviolet (DUV), electron beam (EB), or any combination thereof.

In some embodiments, operation 150 includes EUV lithography of the EUV photoresist layer 230, wherein the EUV lithography process includes exposing a plurality of regions of the EUV photoresist layer 230 to electromagnetic radiation. EUV lithographaphy process may include passing EUV radiation through any one or more suitable EUV photomasks to expose the plurality of regions of the EUV photoresist layer 230. During the EUV lithography process of operation 150, the temperature of the substrate may be in the range of about 10° C. to about 250° C. The temperature of the photoresist structure 200c within the processing chamber may be controlled by a chiller or a heating element.

In one or more embodiments, the radiation exposed regions 240 contain cross-linked moieties from the first and second precursors, thus forming a metal oxide (otherwise referred to as “metal-oxo”) film having both EUV exposed and unexposed regions with different solubility in a developer gas or developer solution. This allows for differing resist architectures to be developed upon subsequent dry development techniques. In some embodiments of the dry development techniques, the radiation exposed regions 240 of the photoresist structure 200c are removed and the unexposed regions of the EUV photoresist layer 230 remain to produce a positive tone resist. In some embodiments of the dry development techniques, the unexposed regions of the EUV photoresist layer 230 are removed and the radiation exposed regions 240 remain to produce a negative tone resist.

At operation 160 of the method 100, the photoresist structure 200c including both unexposed regions of the EUV photoresist layer 230 and radiation exposed regions 240 is subjected to a post exposure treatment and pre-photoresist development process. In some embodiments of operation 160, the process applied to the photoresist structure 200c includes exposure to a first treatment gas, followed by exposure to a purge gas. In some embodiments, operation 160 is performed before performing a dry development process, and thus operation 160 may include exposing the photoresist structure 200c to a first treatment gas containing one or more fluorinating agents for a predetermined period of time. The photoresist structure 200c is then exposed to a purge gas for a predetermined period of time.

In some embodiments, the first treatment gas of operation 160 includes one or more fluorinating agents including hydrogen fluoride (HF), ammonium fluoride (NH₄F), sulfur hexafluoride (SF₆), nitrogen trifluoride (NF₃), xenon difluoride (XeF₂), fluorine (F₂), or any combination thereof. In one or more embodiments, the first treatment gas of operation 160 can include one or more diluting gases or carrier gases, such as argon, nitrogen (N₂), neon, helium, or any combination thereof. In at least one embodiment, the first treatment gas of operation 160 can include one or more etchants including chlorine (Cl₂), bromine (Br₂), iodine (I₂), hydrogen chloride (HCl), hydrogen bromide (HBr), hydrogen iodide (HI), boron trichloride (BCl₃), thionyl chloride (SOCl₂), methanesulfonyl chloride (CH₃SO₂Cl), trichloromethanesulfonyl chloride (CCl₃SO₂Cl), 4-toluenesulfonyl chloride (tosyl chloride), trimethylsilyl bromide, thionyl bromide (SOBr₂), sulfuryl chloride (SO₂Cl₂), and sulfuryl bromide (SO₂Br₂), oxalyl chloride (ClCOCOCl), tert-butyl hypochlorite ((CH₃)₃COCl), N-chlorophthalimide, 1,3-dichloro-5,5-dimethylhydantoin, trimethylsilyl chloride, HCl, Cl₂, PCl₅, BCl₃, HBr, Br₂, CCl₃Br, CBr₄, 1,2-dibromo-1,1,2,2-tetrachloroethane (Cl₂CBrCBrCl₂), BBr₃, PBr₃, N-bromosuccinimide, N-bromoacetamide, 2-bromo-2-cyano-N,N-dimethylacetamide, 1,3-dibromo-5,5-dimethylhydantoin, 2,4,4,6-tetrabromo-2,5-cyclohexadienone, or any combination thereof.

During operation 160, the processing region may be heated to and/or maintained at a temperature ranging from about 100° C. to about 300° C., such as about 125° C. to about 275° C., such as about 150° C. to about 250° C., alternatively about 100° C. to about 125° C., alternatively about 125° C. to about 150° C., alternatively about 150° C. to about 200° C., alternatively about 200° C. to about 250° C., alternatively about 250° C. to about 275° C., alternatively about 275° C. to about 300° C. Additionally and/or alternatively, the processing region during operation 160 may be maintained at a pressure ranging from about 0.1 Torr to about 50 Torr, such as about 0.1 Torr to about 25 Torr, such as about 0.1 Torr to about 10 Torr. The flow rate of the first treatment gas of operation 160 may be introduced to the processing chamber at a flow rate of about 1 sccm to about 2,000 sccm, such as about 100 sccm to about 1,500 sccm, such as about 500 sccm to about 1,000 sccm, alternatively about 1 sccm to about 100 sccm, alternatively about 100 sccm to about 500 sccm, alternatively about 1,000 sccm to about 1,500 sccm, alternatively about 1,500 sccm to about 2,000 sccm. In at least one embodiment, the photoresist structure 200c is exposed to a continuous flow of the first treatment gas during and/or throughout operation 160. In at least one embodiment, the photoresist structure 200c is exposed to discontinuous pulses of the first treatment gas during and/or throughout operation 160. In at least one embodiment, the photoresist structure is exposed to the first treatment gas of operation 160 for about 0.1 s to about 60 s, such as about 0.5 s to about 30 s, such as about 1 s to about 15 s, alternatively about 0.1 s to about 0.5 s, alternatively about 0.5 s to about 1 s, alternatively about 1 s to about 15 s, alternatively about 15 s to about 30 s, alternatively about 30 s to about 60 s.

Following exposure of the photoresist structure 200c with the first treatment gas, the processing region is purged with a purge gas for a predetermined period of time. The processing environment may be evacuated during the purge process—so to reduce or remove remnants of the first treatment gas, products, byproducts, and/or purge gas. The purge gas may include one or more of argon, N₂, H₂, neon, helium, or any combination thereof. The flow rate of purge gas into the processing chamber may be about 1 sccm to about 2,000 sccm, such as about 100 sccm to about 1,500 sccm, such as about 500 sccm to about 1,000 sccm, alternatively about 1 sccm to about 100 sccm, alternatively about 100 sccm to about 500 sccm, alternatively about 1,000 sccm to about 1,500 sccm, alternatively about 1,500 sccm to about 2,000 sccm. In at least one embodiment, the purge gas is supplied to the processing chamber as a continuous flow or as discontinuous pulses. In at least one embodiment, the purge gas is introduced to the processing chamber for about 0.1 s to about 60 s, such as about 0.5 s to about 30 s, such as about 1 s to about 15 s, alternatively about 0.1 s to about 0.5 s, alternatively about 0.5 s to about 1 s, alternatively about 1 s to about 15 s, alternatively about 15 s to about 30 s, alternatively about 30 s to about 60 s.

The metal-oxo film of the photoresist structure 200c can further include an organometal-oxo photoresist material (e.g., an organoindium-oxo photoresist material) in the radiation exposed regions 240 and/or the unexposed regions of the EUV photoresist layer 230 prior to operation 160. Without being bound by theory, the organometal-oxo photoresist material is converted to at least one or more non-volatile solid materials during operation 160. The first treatment process may also produce one or more volatile or gaseous materials from a reaction between the organometal-oxo photoresist material and the first treatment gas. In some embodiments, during operation 160 the organometal-oxo photoresist material is converted to a fluorometal-oxo photoresist material (e.g., a fluoroindium-oxo photoresist materials). In one or more embodiments, the metal-oxo photoresist contains an organoindium-oxo photoresist material in the radiation exposed regions 240 prior to operation 160. In one or more embodiments, the metal-oxo photoresist contains an organoindium-oxo photoresist material in the unexposed regions of the EUV photoresist layer 230 prior to operation 160. The organoindium-oxo photoresist material may be converted to one or more fluoroindium-oxo photoresist materials (e.g., non-volatile or solid materials) during operation 160.

At operation 170 of the method 100, the photoresist structure 200c resulting from operation 160 is exposed to a developer treatment gas to remove one of either the unexposed regions of the EUV photoresist layer 230 or the radiation exposed regions 240 to produce at least one of the photoresists structures 200d and/or 200e, as depicted in FIGS. 2D and 2E respectively. In some embodiments, the developer treatment gas includes one or more halogen containing and/or organic acid containing gases. The halogen containing gases may include fluorine (F), chlorine (Cl), bromine (Br) or iodine (I), or any combination thereof. Exemplary halogen containing gases can include F₂, Cl₂, Br₂, I₂, BCl₃, SF₆, XeF₂, NF₃, hydrogen halides (e.g., HF, HCl, HBr, and HI) and carbon halides (e.g., CF₄, CCl₄, CHₓCl_{y}, CHₓBr_{y}), or any combination thereof. Exemplary organic acids may be or include formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof. In some embodiments, the developer treatment gas further contains a diluting gas or a carrier gas combined with the organic acid during operation 170. Exemplary diluting gases or carrier gases may be or include argon, nitrogen (N₂), hydrogen (H₂), water, neon, helium, or any combination thereof.

In some embodiments, the developer treatment gas of operation 170 includes a gaseous acid, such as HF, HCl, HBr, HI, and other carbonic acids. In one example, the developer treatment gas of operation 170 includes one or more gas(es), such as Cl₂, Br₂, H₂, HBr, HCl, BCl₃, CHₓCl_{y}, CH₄, BBr₃, and CHₓBr_{y}, and combinations thereof. In some embodiments, the developer treatment gas of operation 170 includes a metal containing precursor represented by either MXₐL_{b} or MO_{c}XₐL_{b}, wherein M is a metal (e.g., Mo, Ta, Nb, W, In, or Sn), X is a halogen (e.g., F, Cl, Br, or I), L is an organic ligand (e.g., an amino, a methlyamino, a dimethylamino, an alkoxy, a carboxylate, a halide, an acetate, or an acetylacetonate groups), O is oxygen, and a, b, and c are individually integers ranging from 0 to 6. In some embodiments, the developer treatment gas of operation 170 includes a compound represented by AₓB_{y}, wherein A is selected from B, Al, Si, C, S, and SO; B is selected from Cl, H, Br, F, and CH₄; both x and y are integers greater than 0.

During operation 170, the processing region may be heated to and/or maintained at a temperature ranging from about room temperature (e.g., 20° C.) to about 300° C., such as about 50° C. to about 300° C., 100° C. to about 300° C., such as about 125° C. to about 275° C., such as about 150° C. to about 250° C., alternatively about 100° C. to about 125° C., alternatively about 125° C. to about 150° C., alternatively about 150° C. to about 200° C., alternatively about 200° C. to about 250° C., alternatively about 250° C. to about 275° C., alternatively about 275° C. to about 300° C. Additionally and/or alternatively, the processing region during operation 170 may be maintained at a pressure ranging from about 0.1 Torr to about 50 Torr, such as about 0.1 Torr to about 25 Torr, such as about 0.1 Torr to about 10 Torr. The flow rate of the developer treatment gas of operation 170 may be introduced to the processing chamber at a flow rate of about 1 sccm to about 2,000 sccm, such as about 100 sccm to about 1,500 sccm, such as about 500 sccm to about 1,000 sccm, alternatively about 1 sccm to about 100 sccm, alternatively about 100 sccm to about 500 sccm, alternatively about 1,000 sccm to about 1,500 sccm, alternatively about 1,500 sccm to about 2,000 sccm. In at least one embodiment, at least one of the photoresist structures 200d and/or 200e is exposed to a continuous flow of the developer treatment gas during and/or throughout operation 170. In at least one embodiment, at least one of the photoresist structures 200d and/or 200e is exposed to discontinuous pulses of the developer treatment gas during and/or throughout operation 170. In at least one embodiment, the photoresist structure is exposed to the developer treatment gas of operation 170 for about 1 s to about 300 s, such as about 50 s to about 250 s, such as about 100 s to about 200 s, alternatively about 5 s to about 50 s, alternatively about 50 s to about 100 s, alternatively about 100 s to about 150 s, alternatively about 150 s to about 200 s, alternatively about 200 s to about 250 s, alternatively about 250 s to about 300 s.

Following exposure of at least one of the photoresist structures 200d and/or 200e with the developer treatment gas, the processing region is purged with a purge gas for a predetermined period of time. The processing environment may be evacuated during the purge process—so to reduce or remove remnants of the developer gas, products, byproducts, and/or purge gas. The purge gas may include one or more of argon, N₂, H₂, neon, helium, or any combination thereof. The flow rate of purge gas into the processing chamber may be about 1 sccm to about 2,000 sccm, such as about 100 sccm to about 1,500 sccm, such as about 500 sccm to about 1,000 sccm, alternatively about 1 sccm to about 100 sccm, alternatively about 100 sccm to about 500 sccm, alternatively about 1,000 sccm to about 1,500 sccm, alternatively about 1,500 sccm to about 2,000 sccm. In at least one embodiment, the purge gas is supplied to the processing chamber as a continuous flow or as discontinuous pulses. In at least one embodiment, the purge gas is introduced to the processing chamber for about 0.1 s to about 60 s, such as about 0.5 s to about 30 s, such as about 1 s to about 15 s, alternatively about 0.1 s to about 0.5 s, alternatively about 0.5 s to about 1 s, alternatively about 1 s to about 15 s, alternatively about 15 s to about 30 s, alternatively about 30 s to about 60 s.

In some embodiments, operation 170 may be repeated multiple times to achieve the desired photoresist structure. Operation 170 may be repeated 1 time to 100 times, such as 1 time to 50 times, such as 1 time to 25 times, such as 1 time to 10 times, such as 1 time to 5 times. In some embodiments, operations 160 and 170 may be repeated multiple times in series to achieve the desired photoresist structure. Operations 160 and 170 may be repeated in series 1 time to 100 times, such as 1 time to 50 times, such as 1 time to 25 times, such as 1 time to 10 times, such as 1 time to 5 times.

In at least one embodiment, operation 170 is conducted to remove the unexposed regions of the EUV photoresist layer 230, resulting in the photoresist structure 200d. In which case, the remaining radiation exposed regions 240 may include a height (as determined by measuring the distance between the top of the underlayer 220 and the top of the radiation exposed region 240) of about 5 nm to about 40 nm, such as about 10 nm to about 30 nm, such as about 15 nm to about 25 nm, alternatively about 5 nm to about 10 nm, alternatively about 10 nm to about 15 nm, alternatively about 15 nm to about 20 nm, alternatively about 20 nm to about 25 nm, alternatively about 25 nm to about 30 nm, alternatively about 30 nm to about 40 nm. In at least one embodiment, operation 170 is conducted to remove the radiation exposed regions of the EUV photoresist layer 230, resulting in a photoresist structure 200e having only the unexposed regions of the EUV photoresist layer 230 remaining. In which case, the remaining unexposed regions of the EUV photoresist layer 230 may include a height of about 5 nm to about 40 nm, such as about 10 nm to about 30 nm, such as about 15 nm to about 25 nm, alternatively about 5 nm to about 10 nm, alternatively about 10 nm to about 15 nm, alternatively about 15 nm to about 20 nm, alternatively about 20 nm to about 25 nm, alternatively about 25 nm to about 30 nm, alternatively about 30 nm to about 40 nm.

At operation 180 of the method 100, the photoresist structure 200d or 200e resulting from operation 170 is removed from the processing chamber, and the processing chamber is subjected to a chamber cleaning operation. The processes performed in operation 180 may be performed to clean any one of the processing chambers used to perform one or more of the operations 120-170. The chamber cleaning operation of operation 180 is directed to removing and/or passivating indium containing particles, thin film deposits, and other debris present within the processing chamber and/or on the chamber walls. Generally, the chamber cleaning operation is conducted by reacting the indium containing residue, particles, thin film deposits, and other debris into volatile products which would be carried away with the purge gas. The chamber cleaning operation is conducted by introducing various gases into the process chamber with or without a direct plasma source (e.g., CCP or ICP plasma source) or a remote plasma source (RPS).

The gases used in the chamber cleaning operation of operation 180 may include one or more removal gases, such as Cl₂, CₓF_{y}, NF₃, HCl, HF, H₂, N₂, NH₃, H₂O, O₂, O₃, and combinations thereof. The gases used in the chamber cleaning operation of operation 180 may further include one or more inert purge gases, such as He, Ar, and N₂. In some embodiments, the chamber cleaning operation includes co-flowing the removal gas(es) with the inert purge gas(es) to react with the residue, particles, thin film deposits, and other debris. In some embodiments, the chamber cleaning operation can be conducted with or without a remote plasma source. In one or more embodiments, the process chamber is purged with one or more inert purge gas(es) and cycled between high pressure (e.g., about 5 Torr to about 100 Torr) and low pressure (e.g., about 100 mTorr to about 5 Torr).

The present disclosure relates to methods of forming EUV sensitive photoresists, such as organoindium photoresists. The method described herein implements various deposition, treatment, and lithographic processes to prepare photoresist structures having a substrate, an underlayer, and a EUV sensitive photoresist layer. Upon partial exposure to EUV, a portion of the EUV sensitive photoresist layer (either the radiation exposed region or the unexposed region) may be removed, resulting in a patterned photoresist structure. Additionally, the process steps described herein can be independently optimized, or co-optimized, to provide increased photoresist resolution, process efficiency, process performance, and cost effectiveness. Furthermore, processes disclosed herein can be fine-tuned and/or optimized for proficient preparation of indium-based and/or organoindium based resist structures.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method for preparing a photoresist structure, the method comprising:
depositing an underlayer onto a substrate;
depositing an EUV photoresist layer onto the underlayer, the EUV photoresist layer comprising at least one indium-based compound;
pretreating the EUV photoresist layer to form a pretreated EUV photoresist layer;
exposing the pretreated EUV photoresist layer to a treatment gas to form a treated EUV photoresist layer, wherein the exposure of the pretreated EUV photoresist layer to the treatment gas is performed after a plurality of regions of the pretreated EUV photoresist are exposed to electromagnetic radiation; and
exposing the treated EUV photoresist layer to a developer gas to form a patterned photoresist layer.

2. The method of claim 1, wherein the at least one indium based compound is represented by InRₓL_{y}, wherein R is an organic group, L is a ligand, and both x and y are integers independently ranging from 0 to 3.

3. The method of claim 2, wherein R is an alkyl group.

4. The method of claim 2, wherein R is selected from the group consisting of i-propyl, n-propyl, t-butyl, i-butyl, n-butyl, sec-butyl, n-pentyl, i-pentyl, t-pentyl, sec-pentyl, cyclopentadienyl, and combinations thereof.

5. The method of claim 2, wherein L is selected from the group consisting of an amino, a methyl amino, a dimethyl amino, an alkoxy, a carboxylate, a halide, an acetate, an acetylacetonate, and combinations thereof.

6. The method of claim 1, wherein the at least one indium based compound is selected from the group consisting of trimethyl indium, indium acetate (hydrate), indium nitrate (hydrate), indium acetylacetonate, and combinations thereof.

7. The method of claim 1, wherein pretreating the EUV photoresist layer comprises baking the EUV photoresist layer at a temperature of about 80° C. to about 250° C. for about 5 seconds to about 300 seconds.

8. The method of claim 1, wherein pretreating the EUV photoresist layer comprises applying a UV treatment to the EUV photoresist layer, the UV treatment comprising a UV radiation source capable of providing UV light at a wavelength of about 125 nm to about 405 nm.

9. The method of claim 1, wherein pretreating the EUV photoresist layer comprises:
baking the EUV photoresist layer at a temperature of about 80° C. to about 250° C. for about 5 seconds to about 300 seconds; and
applying a UV treatment to the EUV photoresist layer.

10. The method of claim 1, wherein the treatment gas includes one or more fluorinating agents selected from the group consisting of hydrogen fluoride (HF), ammonium fluoride (NH₄F), sulfur hexafluoride (SF₆), nitrogen trifluoride (NF₃), xenon difluoride (XeF₂), fluorine (F₂), or any combination thereof.

11. The method of claim 1, wherein the developer gas includes one or more organic acid selected from the group consisting of formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, and combinations thereof.

12. A method for preparing a photoresist structure, the method comprising:
depositing an underlayer onto a substrate;
depositing an EUV photoresist layer onto the underlayer, the EUV photoresist layer comprising at least one indium-based compound represented by InRₓL_{y}, wherein R is an organic group, L is a ligand, and both x and y are integers independently ranging from 0 to 3;
pretreating the EUV photoresist layer to form a pretreated EUV photoresist layer;
performing a EUV lithography process on the pretreated EUV photoresist layer to form a patterned EUV photoresist layer;
exposing the patterned EUV photoresist layer to a treatment gas to form a treated EUV photoresist layer;
exposing the treated EUV photoresist layer to a developer gas to form the photoresist structure.

13. The method of claim 12, wherein R is an alkyl group.

14. The method of claim 12, wherein R is selected from the group consisting of i-propyl, n-propyl, t-butyl, i-butyl, n-butyl, sec-butyl, n-pentyl, i-pentyl, t-pentyl, sec-pentyl, cyclopentadienyl, and combinations thereof.

15. The method of claim 12, wherein L is selected from the group consisting of an amino, a methyl amino, a dimethyl amino, an alkoxy, a carboxylate, a halide, an acetate, an acetylacetonate, and combinations thereof.

16. The method of claim 12, wherein the at least one indium based compound is selected from the group consisting of trimethyl indium, indium acetate (hydrate), indium nitrate (hydrate), indium acetylacetonate, and combinations thereof.

17. The method of claim 12, wherein pretreating the EUV photoresist layer comprises baking the EUV photoresist layer at a temperature of about 80° C. to about 250° C. for about 5 seconds to about 300 seconds.

18. The method of claim 12, wherein pretreating the EUV photoresist layer comprises applying a UV treatment to the EUV photoresist layer, the UV treatment comprising a UV lightsource capable of providing UV light at a wavelength of about 125 nm to about 405 nm.

19. The method of claim 12, wherein pretreating the EUV photoresist layer comprises:
baking the EUV photoresist layer at a temperature of about 80° C. to about 250° C. for about 5 seconds to about 300 seconds; and
applying a UV treatment to the EUV photoresist layer.

20. The method of claim 12, wherein
the treatment gas includes one or more fluorinating agents selected from the group consisting of hydrogen fluoride (HF), ammonium fluoride (NH₄F), sulfur hexafluoride (SF₆), nitrogen trifluoride (NF₃), xenon difluoride (XeF₂), fluorine (F₂), or any combination thereof; and
the developer gas includes one or more organic acid selected from the group consisting of formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, and combinations thereof.
